(19) United States
(12) Patent Application Publication
(10) Pub. No.: US 2023/0257258 A1
(43) Pub. Date: Aug. 17, 2023

(54) SEMICONDUCTOR DEVICE AND SENSOR MODULE

(71) Applicant: ROHM CO., LTD., Kyoto (JP)

(72) Inventors: Martin Wilfried HELLER, Kyoto (JP); Toma FUJITA, Kyoto (JP)

(73) Assignee: ROHM CO., LTD., Kyoto (JP)

(21) Appl. No.: 18/164,844

(22) Filed: Feb. 6, 2023

(30) Foreign Application Priority Data
Feb. 14, 2022 (JP) 2022-020497
Feb. 14, 2022 (JP) 2022-020498
Oct. 18, 2022 (JP) 2022-166929

(51) Int. Cl. B81B 7/02; B81B 7/00; G01L 9/00; G01L 17/00; G01P 15/125; G01L 19/00; B60C 23/04

(52) U.S. Cl. CPC B81B 7/02; B81B 7/0074; G01L 9/0052; G01L 17/00; G01P 15/125; G01L 19/0092; B60C 23/0488; B81B 2201/0235; B81B 2201/0264; B81B 2203/0127; B81B 2203/0136; B81B 2203/04

(57) ABSTRACT

A semiconductor device includes a sensor structure body, a gas conduit that extends from a surface of the sensor structure body toward a hollow space in the sensor structure body to introduce a gas into the hollow space from outside, a pressure sensor that is formed inside the sensor structure body and has a membrane which is able to vibrate by actions of the gas, an acceleration sensor that is formed inside the sensor structure body to detect an acceleration that has acted on the sensor structure body, and a sealing resin that covers the sensor structure body, in which the gas conduit includes an inner end portion on the hollow space side and an outer end portion on the end surface side of the sensor structure body, and the outer end portion of the gas conduit is opened on an end surface of the sealing resin.

### CROSS-REFERENCE TO RELATED APPLICATIONS

The present application corresponds to Japanese Patent Application No. 2022-20497 filed with the Japan Patent Office on Feb. 14, 2022, Japanese Patent Application No. 2022-20498 filed with the Japan Patent Office on Feb. 14, 2022, and Japanese Patent Application No. 2022-166929 filed with the Japan Patent Office on Oct. 18, 2022, and the entire disclosures of the applications are incorporated herein by reference.

### TECHNICAL FIELD

The present disclosure relates to a semiconductor device that includes a pressure sensor and also relates to a sensor module.

### BACKGROUND ART

Patent Document 1 (Japanese Patent Application Publication No. 2021-25966) discloses a MEMS sensor. The MEMS sensor includes a silicon substrate that has a first surface and a second surface on a side opposite to the first surface and has a cavity in the first surface, a silicon diaphragm that has a first surface and a second surface on a side opposite to the first surface and in which the second surface is bonded directly to the first surface of the silicon substrate, and a piezoresistance that is formed on the first surface of the silicon diaphragm, and in the MEMS sensor, a plane orientation of the first surface of the silicon substrate and a plane orientation of the first surface of the silicon diaphragm differ from each other.

### SUMMARY OF INVENTION

A preferred embodiment the present disclosure provides a semiconductor device in which a pressure sensor and an acceleration sensor are packaged by a common sealing resin.

A semiconductor device according to a preferred embodiment of the present disclosure includes a sensor structure body that has a hollow space inside, a gas conduit that extends from an end surface of the sensor structure body toward the hollow space to introduce a gas into the hollow space from outside the sensor structure body, a pressure sensor that is formed inside the sensor structure body and has a membrane which is able to vibrate by actions of a pressure of the gas introduced into the hollow space via the gas conduit, an acceleration sensor that is formed inside the sensor structure body to detect an acceleration which has acted on the sensor structure body, and a sealing resin that covers the sensor structure body, in which the gas conduit includes an inner end portion on the hollow space side and an outer end portion on the end surface side of the sensor structure body, and the outer end portion of the gas conduit is opened on an end surface of the sealing resin.

### Effects of Invention

According to the semiconductor device according to a preferred embodiment of the present disclosure, since the pressure sensor and the acceleration sensor are covered by the common sealing resin, it is possible to detect both a pressure around the semiconductor device and an acceleration acting on the semiconductor device by one chip.

### BRIEF DESCRIPTION OF DRAWINGS

FIG. 1 is a schematic perspective view of a semiconductor device according to a first preferred embodiment of the present disclosure.

FIG. 2 is a schematic side view of the semiconductor device according to the first preferred embodiment of the present disclosure.

FIG. 3 is a schematic plan view of the semiconductor device according to the first preferred embodiment of the present disclosure.

FIG. 4 is a schematic plan view which shows a sensor structure of a first semiconductor substrate shown in FIG. 1.

FIG. 5 is a schematic plan view which shows a sensor structure of a second semiconductor substrate shown in FIG. 1.

FIG. 6 is a diagram which schematically shows a cross-sectional structure of a pressure sensor.

FIG. 7 is a diagram that shows a three-dimensional shape of a second cavity of the second semiconductor substrate and that of a gas conduit extending from the second cavity.

FIG. 8 is a diagram that schematically shows a cross-sectional structure of an acceleration sensor.

FIG. 9A to FIG. 9C are each a diagram that shows a step related to formation of the gas conduit shown in FIG. 6.

FIG. 10A to FIG. 10C are each a diagram that shows a step related to singulation of the plurality of semiconductor devices.

FIG. 11 is a schematic perspective view of a semiconductor device according to a second preferred embodiment of the present disclosure.

FIG. 12 is a schematic plan view that shows a sensor structure of the first semiconductor substrate shown in FIG. 1.

FIG. 13 is a schematic plan view that shows a sensor structure of the second semiconductor substrate shown in FIG. 1.

FIG. 14A and FIG. 14B are each a diagram that shows a step related to singulation of the plurality of semiconductor devices.

FIG. 15 is a diagram that shows an installation state when the semiconductor device is used as a tire pressure sensor.

### DESCRIPTION OF EMBODIMENTS

Next, a detailed description will be given of the preferred embodiments of the present disclosure with reference to the attached drawings.

[Entire Configuration of Semiconductor Device 1 According to First Preferred Embodiment]

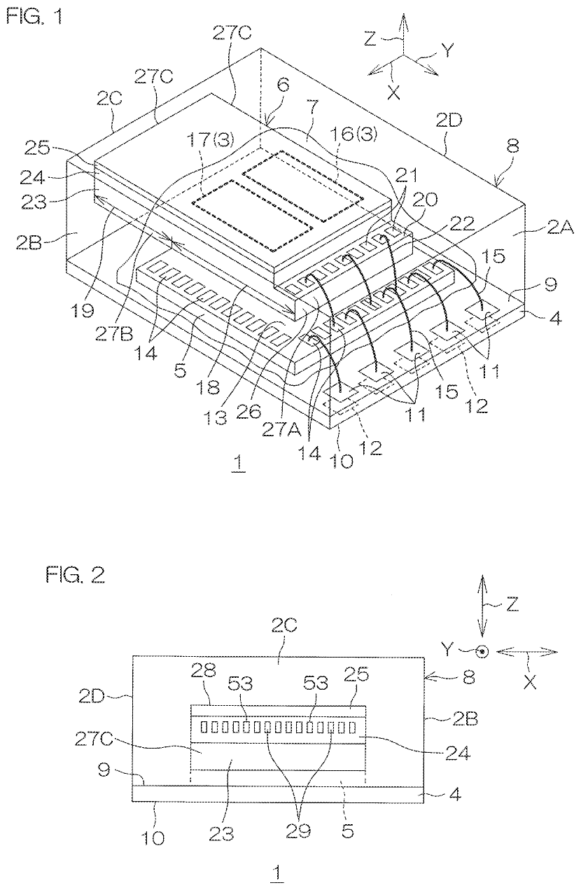

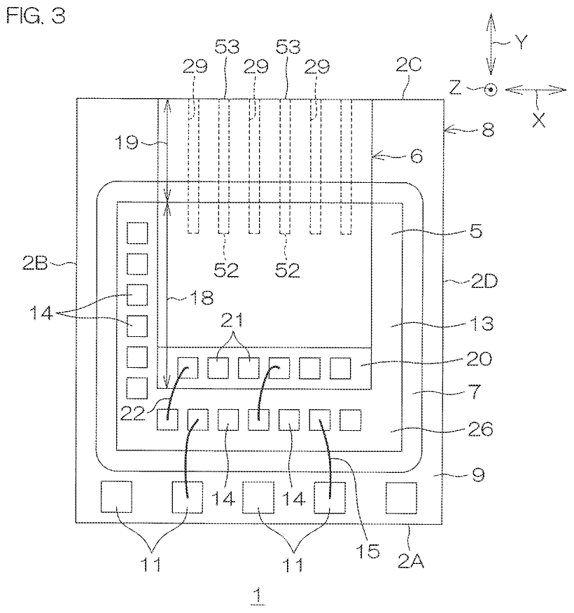

FIG. 1 is a schematic perspective view of a semiconductor device 1 according to the first preferred embodiment of the present disclosure. FIG. 2 is a schematic side view of the semiconductor device 1 according to the first preferred embodiment of the present disclosure. FIG. 3 is a schematic plan view of the semiconductor device 1 according to the first preferred embodiment of the present disclosure. In FIG. 1 and FIG. 3, for clarification of an inner structure of the semiconductor device 1, an interior of a sealing resin 8 is shown transparently.

Hereinafter, three directions orthogonal to each other are defined as a first direction X, a second direction Y and a third direction Z. The third direction Z may be a thickness direction of the semiconductor device 1. The first direction X and the second direction Y may be respectively a direction along a first end surface 2A and a third end surface 2C of the semiconductor device 1 as well as a second end surface 2B and a fourth end surface 2D thereof. The first end surface 2A and the third end surface 2C are surfaces that are parallel to each other. The second end surface 2B and the fourth end surface 2D are surfaces that are orthogonal to the first end surface 2A and the third end surface 2C and also parallel to each other.

The semiconductor device 1 is a composite sensor capable of detecting a plurality of physical quantities. In this preferred embodiment, the semiconductor device 1 is a sensor that detects at least a gas pressure and an acceleration. The semiconductor device 1 is constituted of one over-mold package that is formed by covering a semiconductor chip having a plurality of built-in sensors by the sealing resin 8. The semiconductor device 1 is formed as a chip, for example, in a rectangular parallelepiped shape. Since a sensor structure 3 of the semiconductor device 1 is formed by MEMS technology, the semiconductor device 1 may be referred to as a MEMS sensor.

The semiconductor device 1 includes a supporting substrate 4, a circuit substrate 5, a sensor structure body 6, a liquid-type curing sealing material 7, and the sealing resin 8. The sealing resin 8 collectively covers the circuit substrate 5, the sensor structure body 6 and the liquid-type curing sealing material 7 on an upper surface region of the supporting substrate 4. Except for a part of the sensor structure body 6, entire peripheries around the circuit substrate 5, the sensor structure body 6, and the liquid-type curing sealing material 7 are covered by the sealing resin 8. By appearance, the semiconductor device 1 has a stacked structure of the supporting substrate 4 and the sealing resin 8 stacked on the supporting substrate 4. An end surface of the stacked structure of the supporting substrate 4 and the sealing resin 8 is exposed over the entire circumferential direction of the first to fourth end surfaces 2A to 2D of the semiconductor device 1. The first to fourth end surfaces 2A to 2D of the semiconductor device 1 may be each defined as first to fourth end surfaces 2A to 2D of the supporting substrate 4 and the sealing resin 8.

The supporting substrate 4 may be, for example, an insulating substrate such as a known printed circuit board (PCB), a ceramic substrate, etc. The supporting substrate 4 is formed in a quadrilateral plate shape having an upper surface 9 and a rear surface 10. The upper surface 9 of the supporting substrate 4 may be an element chip surface on which various types of element chips are mounted, and the rear surface 10 of the supporting substrate 4 may be a mounting surface that is bonded to a mounting substrate.

A plurality of electrode pads 11 are formed on the upper surface 9 of the supporting substrate 4. The electrode pad 11 is an internal pad that is disposed inside the sealing resin 8. A plurality of terminal pads 12 (external pads) corresponding to the plurality of electrode pads 11 are formed on the rear surface 10 of the supporting substrate 4. The plurality of terminal pads 12 face the plurality of electrode pads 11 on a one-on-one basis, for example, in a thickness direction of the supporting substrate 4. Via a through electrode (not shown) that penetrates through the supporting substrate 4, the terminal pad 12 and the electrode pad 11 are electrically connected to each other. The plurality of electrode pads 11 and the plurality of terminal pads 12 are selectively disposed, for example, at an end portion of the supporting substrate 4 on one side in the second direction Y.

The circuit substrate 5 is disposed on the upper surface 9 of the supporting substrate 4. The circuit substrate 5 is formed of, for example, a silicon substrate (silicon chip) in a quadrilateral plate shape. Inside the circuit substrate 5, there are formed a charge amplifier that amplifies an electrical signal output from the sensor structure body 6, a filter circuit (low-pass filter: LPF, etc.) that takes out a specific frequency component of the electrical signal, a logic circuit that performs a logical calculation of the electrical signal after filtering, etc. These circuits are constituted of, for example, CMOS devices.

A plurality of electrode pads 14 (circuit pads) are formed on an upper surface 13 of the circuit substrate 5. The plurality of electrode pads 14 are, for example, arrayed at intervals along an outer peripheral edge of the circuit substrate 5. A first wiring member 15 electrically connects the electrode pads 14 of the circuit substrate 5 and the electrode pad 11 of the supporting substrate 4. The first wiring member 15 may be a bonding wire of, for example, gold, copper, aluminum, etc. The first wiring member 15 may be referred to as a first wire.

The sensor structure body 6 is a composite chip in which the plurality of sensor structures 3 are formed on the semiconductor device 1. In this preferred embodiment, the sensor structure body 6 includes a pressure sensor 16 and an acceleration sensor 17 as a plurality of sensors. The sensor structure body 6 is formed of, for example, a silicon substrate (silicon chip) in a quadrilateral plate shape. The sensor structure body 6 is disposed on the upper surface 13 of the circuit substrate 5.

In this preferred embodiment, the sensor structure body 6 includes, in an integral manner, a supported portion 18 that is partially supported by the circuit substrate 5 from below and an extension portion 19 that extends from the supported portion 18 outside a frame of the circuit substrate 5 in a state of floating from the circuit substrate 5. The extension portion 19 of the sensor structure body 6 holds a part of the sealing resin 8 between the extension portion 19 and the supporting substrate 4, while also extending parallel to the upper surface 9 of the supporting substrate 4 and is exposed from the end surfaces 2A to 2D of the sealing resin 8 (refer to FIG. 2). The extension portion 19 of the sensor structure body 6 is selectively exposed from one end surface (third end surface 2C in this preferred embodiment) among the first to fourth end surfaces 2A to 2D of the sealing resin 8.

A plurality of electrode pads 21 (sensor pads) are formed on an upper surface 20 of the sensor structure body 6. The plurality of electrode pads 21 are arrayed at intervals, for example, along an outer peripheral edge of the sensor structure body 6. A second wiring member 22 electrically connects the electrode pads 21 of the sensor structure body 6 and the electrode pads 14 of the circuit substrate 5. The second wiring member 22 may be a bonding wire of, for example, gold, copper, aluminum, etc. The second wiring member 22 may be referred to as a second wire.

The sensor structure body 6 is provided with a first semiconductor substrate 23, a second semiconductor substrate 24 and a lid substrate 25. The first semiconductor substrate 23, the second semiconductor substrate 24, and the lid substrate 25 may be formed of a silicon substrate. The sensor structure 3 is formed each in the first semiconductor substrate 23 and the second semiconductor substrate 24. The first semiconductor substrate 23 and the second semiconductor substrate 24 may be respectively referred to as a first sensor chip and a second sensor chip. The lid substrate 25 covers an upper surface (first principal surface 33 to be described later) of the second semiconductor substrate 24 to protect the sensor structure 3 formed on the second semiconductor substrate 24 from an external force.

The second semiconductor substrate 24 is stacked on the first semiconductor substrate 23, and the lid substrate 25 is stacked on the second semiconductor substrate 24. The first semiconductor substrate 23 has a lead-out portion 26 that is led out onto the second semiconductor substrate 24 and the lid substrate 25 in a horizontal direction (direction along the upper surface 13 of the circuit substrate 5). The plurality of electrode pads 21 are concentrated on the lead-out portion 26. The lead-out portion 26 may be referred to as a pad region in the sensor structure body 6.

With reference to FIG. 2, an end surface 27C of the sensor structure body 6 is exposed from the third end surface 2C of the sealing resin 8. End surfaces 27A to 27D of the sensor structure body 6 are respectively formed by stacked structures of end surfaces of the first semiconductor substrate 23, the second semiconductor substrate 24 and the lid substrate 25, and the third end surface 27C is flush with the third end surface 2C of the sealing resin 8. More specifically, the sensor structure body 6 has the first end surface 27A and the third end surface 27C that face in the second direction Y and are parallel to each other as well as the second end surface 27B and the fourth end surface 27D that face in the first direction X and are parallel to each other. In this preferred embodiment, the third end surface 27C of the sensor structure body 6 is exposed from the third end surface 2C of the sealing resin 8, and the remaining surfaces of the first end surface 27A, the second end surface 27B and the fourth end surface 27D are covered by the sealing resin 8.

An outline 28 of the third end surface 27C of the sensor structure body 6 is exposed to the third end surface 2C of the sealing resin 8 over an entire circumference thereof. The third end surface 27C of the sensor structure body 6 is surrounded by the third end surface 2C of the sealing resin 8. A plurality of gas conduits 29 for introducing a gas into the sensor structure body 6 are opened on the third end surface 27C of the sensor structure body 6. With reference to FIG. 3, the plurality of gas conduits 29 extend from the third end surface 27C (third end surface 2C of sealing resin 8) of the sensor structure body 6 toward the inside of the sensor structure body 6 and has an end inside the sensor structure body 6. As shown in FIG. 3, the plurality of gas conduits 29 may assume a linear shape extending parallel to each other. Although not shown, the plurality of gas conduits 29 may be each formed in a curved shape.

The liquid-type curing sealing material 7 is a sealing material that is formed, for example, by curing a liquid-type resin material. The liquid-type curing sealing material 7 may be formed of a resin that is widely used as a sealing resin, for example, a silicone resin, etc. The liquid-type curing sealing material 7 does not have a fixed shape and is formed in a shape having an uneven surface (curved surface) along an outer shape of the circuit substrate 5 and that of the sensor structure body 6. In this preferred embodiment, the liquid-type curing sealing material 7 selectively covers the circuit substrate 5 and the sensor structure body 6. Specifically, it may cover the circuit substrate 5 and the supported portion 18 of the sensor structure body 6. The extension portion 19 of the sensor structure body 6 is not covered by the liquid-type curing sealing material 7 but may be in non-contact with the liquid-type curing sealing material 7.

The sealing resin 8 assumes an outer shape of the semiconductor device 1 together with the supporting substrate 4 and is formed substantially in a rectangular parallelepiped shape. The sealing resin 8 is constituted of a known molded resin, for example, an epoxy resin, etc., and also covers the circuit substrate 5 and the sensor structure body 6 that are covered by the liquid-type curing sealing material 7. The extension portion 19 of the sensor structure body 6 is directly covered by the sealing resin 8.

[Inner Structure of Sensor Structure Body 6 (Sensor Chip)]

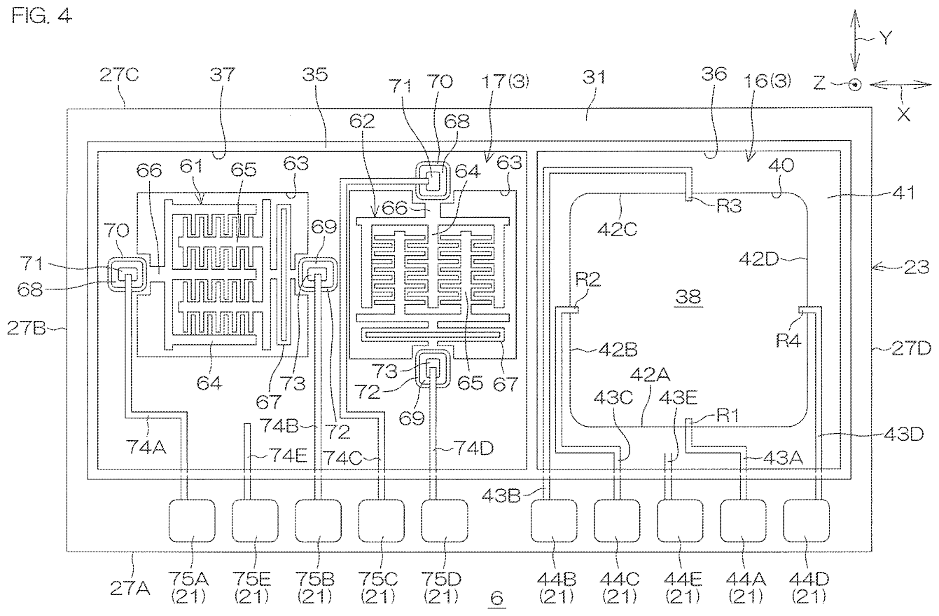

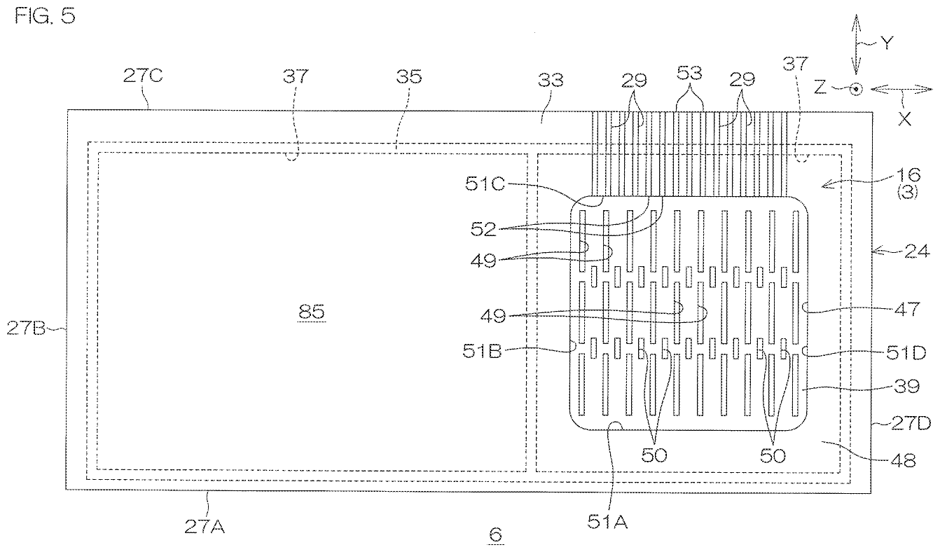

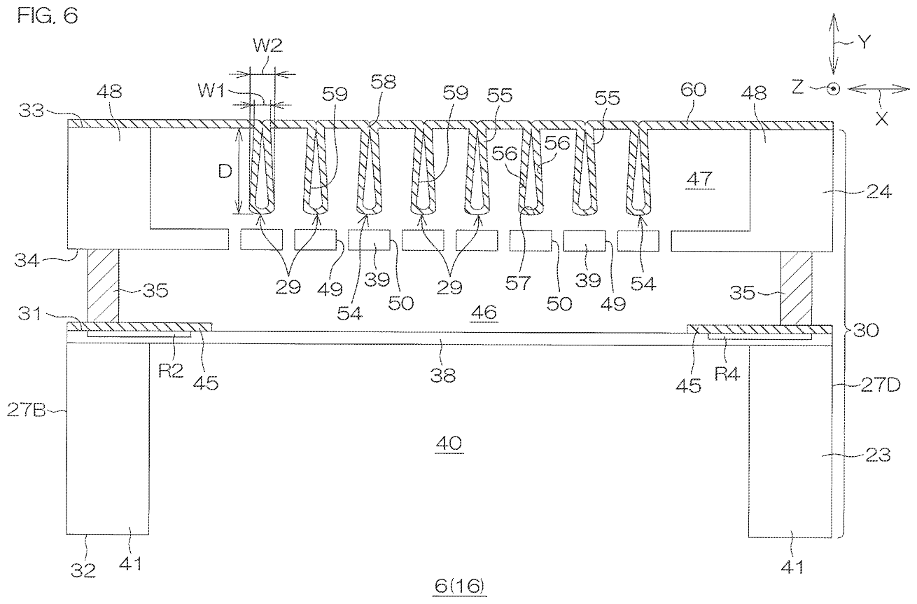

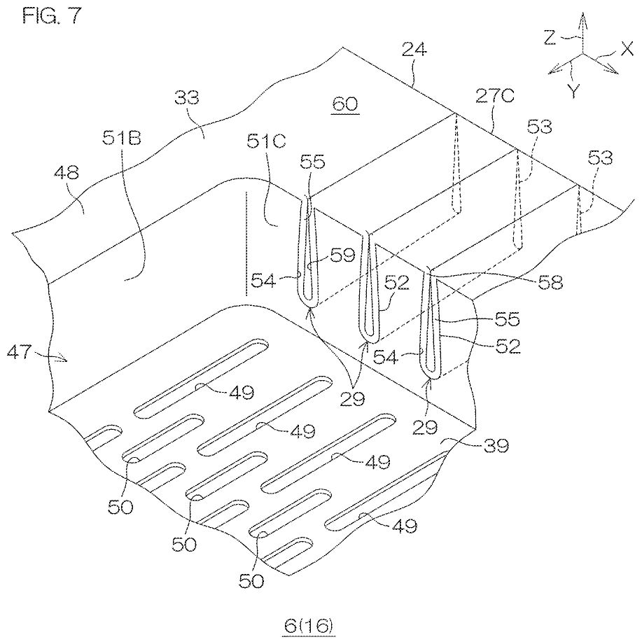

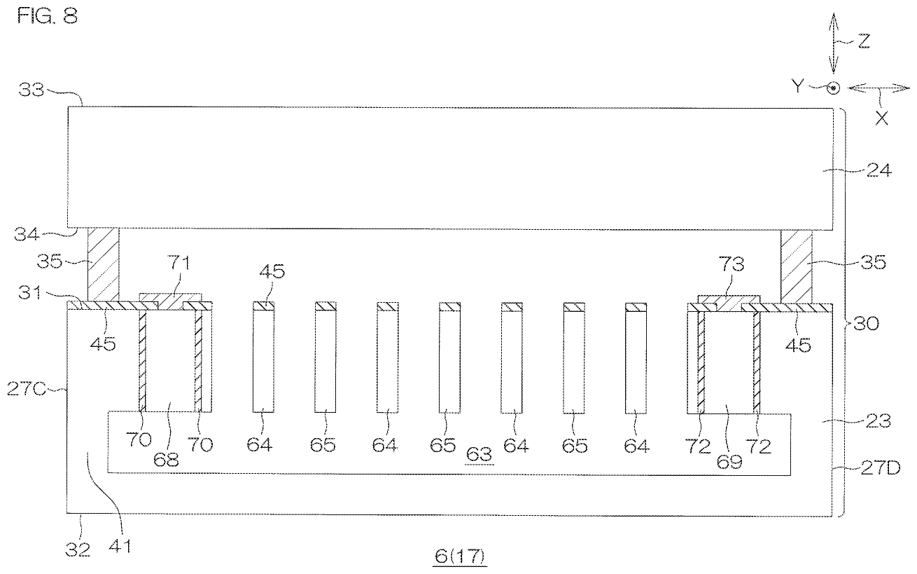

FIG. 4 is a schematic plan view that shows the sensor structure 3 of the first semiconductor substrate 23 in FIG. 1. FIG. 5 is a schematic plan view that shows the sensor structure 3 of the second semiconductor substrate 24 in FIG. 1. FIG. 6 is a diagram that schematically shows a cross-sectional structure of the pressure sensor 16. FIG. 7 is a diagram that shows a three-dimensional shape of a second cavity 47 of the second semiconductor substrate 24 and that of the gas conduit 29 extending from the second cavity 47. FIG. 8 is a diagram which schematically shows a cross-sectional structure of the acceleration sensor 17. FIG. 6 and FIG. 8 extract and show configurations necessary for describing the cross-sectional structures of the pressure sensor 16 and the acceleration sensor 17. However, it should be noted that they do not show a cross section at a particular position in FIG. 4 or FIG. 5. It should be also noted that, in FIG. 4 to FIG. 8, there is a case that a constituent common to a constituent shown in FIG. 1 to FIG. 3 may be different in positional relationship or dimensional ratio.

With reference to FIG. 4 to FIG. 8, the sensor structure body 6 has a substrate stacked structure 30 that includes the first semiconductor substrate 23 and the second semiconductor substrate 24. The first semiconductor substrate 23 has a first principal surface 31 (front surface) and a second principal surface 32 (rear surface) on a side opposite thereto. The second semiconductor substrate 24 has a first principal surface 33 (front surface) and a second principal surface 34 (rear surface) on a side opposite thereto. In a posture that the first principal surface 31 of the first semiconductor substrate 23 faces the second principal surface 34 of the second semiconductor substrate 24, the second semiconductor substrate 24 is bonded to the first semiconductor substrate 23. The first semiconductor substrate 23 and the second semiconductor substrate 24 are fixed to each other by a bonding portion 35. Although not shown in FIG. 4 to FIG. 8, the bonding portion 35 also bonds a space between the second semiconductor substrate 24 and the lid substrate 25.

The bonding portion 35 may be simply referred to as a connection member or may be referred to as a conductive interconnection, an electrical interconnection, etc. The bonding portion 35 may be bonded, for example, by eutectic bonding, solid liquid inter-diffusion (SLID) bonding, thermo-compression (TC) bonding or bonding by using a reactive nanostructure material. In the case of eutectic bonding, the bonding portion 35 may be Al—Ge, Au—Ge, Au—Si, etc. In the case of solid liquid inter-diffusion bonding, the bonding portion 35 may be Cu—Sn, etc. In the case of thermo-compression bonding, the bonding portion 35 may be Cu—Cu, Au—Au, Al—Al, Ti—Al, Ti—Ti, etc. In the case of bonding by a reactive nanostructure material, the bonding portion 35 may be Ni—Al, etc. These bonding methods may be used in combination.

With reference to FIG. 4 and FIG. 5, the bonding portion 35 demarcates a plurality of sensor regions 36, 37 in the substrate stacked structure 30. In this preferred embodiment, the plurality of sensor regions 36, 37 include a first sensor region 36 and a second sensor region 37. The first sensor region 36 may be a region where the pressure sensor 16 is formed and the second sensor region 37 may be a region where the acceleration sensor 17 is formed. The first sensor region 36 and the second sensor region 37 are each formed as a closed region that is closed by the bonding portion 35. The first sensor region 36 and the second sensor region 37 are disposed so as to be aligned to each other.

With reference to FIG. 4 to FIG. 7, a description will be given of a structure of the pressure sensor 16. The pressure sensor 16 is formed in the first sensor region 36. The pressure sensor 16 is formed by processing for partially removing the first semiconductor substrate 23 and the second semiconductor substrate 24 of the substrate stacked structure 30.

The pressure sensor 16 includes a membrane 38, piezoresistances R1 to R4, a protective layer 39, and a gas conduit 29.

With reference to FIG. 6, the membrane 38 is formed on the first principal surface 31 of the first semiconductor substrate 23. The membrane 38 can be formed, for example, by selectively etching the first semiconductor substrate 23. A first cavity 40 is formed in the first semiconductor substrate 23 by the etching. With reference to FIG. 4, the first cavity 40 is a portion surrounded by a first frame portion 41 that is constituted of a portion of the first semiconductor substrate 23 which is not etched.

With reference to FIG. 6, the membrane 38 is integrally connected to an inner edge portion of the first frame portion 41 to block an upper end of the first cavity 40, thereby forming an upper surface of the first cavity 40. The membrane 38 is supported by the first frame portion 41 so as to vibrate in a thickness direction (third direction Z) of the first semiconductor substrate 23. With reference to FIG. 4, the membrane 38 is formed substantially in a quadrilateral shape in a plan view. The membrane 38 is formed by using a part of the first semiconductor substrate 23 (silicon substrate in this preferred embodiment) and, therefore, may be referred to as a silicon membrane or a silicon diaphragm. A thickness of the membrane 38 is not in particular restricted as long as it is a thickness that allows vibration by actions of a gas pressure and may be, for example, not less than 3 μm and not more than 30 μm.

The piezoresistances R1 to R4 are diffusion resistances formed on the first principal surface 31 of the membrane 38 by introducing an impurity such as boron (B), etc., into the membrane 38 and may be referred to as “gauges.” The piezoresistances R1 to R4 are disposed substantially at equal intervals along a circumferential direction of the membrane 38 that is substantially in a quadrilateral shape in a plan view. More specifically, in a plan view, the first piezoresistance R1 is formed by crossing a first side 42A of the membrane 38, the second piezoresistance R2 is formed by crossing a second side 42B of the membrane 38, the third piezoresistance R3 is formed by crossing a third side 42C of the membrane 38, and the fourth piezoresistance R4 is formed by crossing a fourth side 42D of the membrane 38. The first side 42A and the third side 42C may be sides that face in the second direction Y and are parallel to each other. The second side 42B and the fourth side 42D may be sides that face in the first direction X and are parallel to each other. Wirings (first to fourth wirings 43A to 43D) extend respectively from the piezoresistances R1 to R4 and are electrically connected to the electrode pads 21.

The electrode pads 21 may include, for example, a first pad 44A, a second pad 44B, a third pad 44C, a fourth pad 44D and a fifth pad 44E for the pressure sensor 16. The first to fourth pads 44A to 44D may be referred to as a ground terminal (GND), a negative-side voltage output terminal (Vout-), a voltage applying terminal (Vdd) and a positive-side voltage output terminal (Vout⁺), in accordance with their respective connection targets. Further, the fifth pad 44E is a substrate terminal connected to the first semiconductor substrate 23 via the fifth wiring 43E and set to a potential equal to or higher than the voltage applying terminal (Vdd).

A first insulating film 45 may be formed on the first principal surface 31 of the first semiconductor substrate 23. The first insulating film 45 may be, for example, a silicon oxide film. The first insulating film may cover the piezoresistances R1 to R4.

The protective layer 39 is formed on the second principal surface 34 of the second semiconductor substrate 24. The protective layer 39 faces the membrane 38, with an interval kept, in a thickness direction (third direction Z) of the substrate stacked structure 30. A space 46 having a fixed height is formed between the protective layer 39 and the membrane 38. The protective layer 39 faces the membrane 38 with a space 46 interposed therebetween. The space 46 is a space into which a gas flows and may be referred to as a gas flowing space 46.

The protective layer 39 can be formed by selectively etching, for example, the second semiconductor substrate 24. The second cavity 47 is formed by etching in the second semiconductor substrate 24. With reference to FIG. 5, the second cavity 47 is a portion that is surrounded by a second frame portion 48 constituted of a portion of the second semiconductor substrate 24 which is not etched.

With reference to FIG. 6, the protective layer 39 is integrally connected to an inner edge portion of the second frame portion 48 to block a lower end of the second cavity 47, thereby forming a bottom surface of the second cavity 47. With reference to FIG. 5, the protective layer 39 is formed substantially in a quadrilateral shape in a plan view. A thickness of the protective layer 39 is larger than a thickness of the membrane 38, and may be, for example, not less than 10 μm and not more than 50 μm.

With reference to FIG. 5 to FIG. 7, through holes 49, 50 that penetrate through the protective layer 39 in a thickness direction are formed in the protective layer 39. In this preferred embodiment, the plurality of through holes 49, 50 are formed in the protective layer 39. The plurality of through holes 49, 50 may include a first through hole 49 and a second through hole 50 that are different in size from each other. For example, as shown in FIG. 5, in the case of a through slit in which the plurality of through holes 49, 50 linearly extend, the first through hole 49 and the second through hole 50 may be different in length from each other. In FIG. 5, the first through hole 49 is a slit longer than the second through hole 50, and the second through hole 50 is a slit shorter than the first through hole 49. Although not shown, where the plurality of through holes 49, 50 are in a circular shape, the first through hole 49 and the second through hole 50 may be different in diameter from each other.

The plurality of through holes 49, 50 are regularly arrayed on a front surface of the protective layer 39. For example, the plurality of through holes 49, 50 may be arrayed in a matrix form or may be arrayed in a staggered form. In FIG. 5 and FIG. 7, there is shown a pattern in which the plurality of first through holes 49 and the plurality of second through holes 50 are arrayed in a staggered form. For example, a group of the plurality of first through holes 49 that are formed at intervals apart from each other in the second direction Y and a group of the plurality of second through holes 50 that are formed at intervals apart from each other in the second direction Y are alternately arrayed along the first direction X. A staggered pattern is, thereby, formed in which the first through holes 49 or the second through holes 50 do not continue in an oblique direction, respectively.

With reference to FIG. 5, the gas conduit 29 extends from the second cavity 47 up to the end surfaces 27A to 27D of the sensor structure body 6. In this preferred embodiment, of four side surfaces 51A to 51D of the second cavity 47, from the third side surfaces 51C parallel to the third end surface 27C of the sensor structure body 6, it extends up to the third end surface 27C of the sensor structure body 6 via the second frame portion 48. The first side surface 51A as a remaining side surface of the second cavity 47 may be parallel to the first end surface 27A of the sensor structure body 6, the second side surface 51B may be parallel to the second end surface 27B of the sensor structure body 6, and the fourth side surface 51D may be parallel to the fourth end surface 27D of the sensor structure body 6.

With reference to FIG. 5 and FIG. 7, the gas conduit 29 includes an inner end portion 52 on the second cavity 47 side and an outer end portion 53 on the third end surface 27C side of the sensor structure body 6. The outer end portion 53 of the gas conduit 29 is opened on the third end surface 27C of the sensor structure body 6. Therefore, the outer end portion 53 of the gas conduit 29 is also opened on the third end surface 2C of the sealing resin 8 (refer to FIG. 2 and FIG. 3). With reference to FIG. 6 and FIG. 7, the gas conduit 29 is constituted of a trench 54 that is formed in the first principal surface 33 of the second semiconductor substrate 24 and a conduit insulating film 55 that is formed on an inner surface of the trench 54.

The trench 54 is a recessed portion that forms an outline of the gas conduit 29. The trench 54 is formed by selectively digging down a linear region that is a part of the second frame portion 48 from the third side surface 51C of the second cavity 47 to the third end surface 27C of the sensor structure body 6. The trench 54 has a side surface 56 that is curved outwardly from an open end thereof toward a depth direction and also has a bottom-wide shape which gradually increases in width. The trench 54 may have a width W1 at the position that is relatively narrow, for example, at the open end of the trench 54 and a width W2 that is wider than the width W1 in the vicinity of a bottom portion 57 of the trench 54. The width W1 may be, for example, not less than 1 μm and less than 2 μm, and the width W2 may be not less than 2 μm and not more than 3 μm. Further, a depth D of the trench 54 may be not less than 10 μm and not more than 50 μm.

The conduit insulating film 55 extends from the inner end portion 52 of the trench 54 on the second cavity 47 side up to the outer end portion 53 of the trench 54 on the third end surface 27C side of the second semiconductor substrate 24 along a length direction of the trench 54. The conduit insulating film 55 is formed in a tubular shape that is blocked at an upper end of the trench 54 in a depth direction (open end of the trench 54). The conduit insulating film 55 may have, for example, a thickness of about 1 μm.

More specifically, the conduit insulating film 55 is formed so as to branch from the bottom portion 57 of the trench 54 in both directions along the pair of side surfaces 56 in a cross-sectional view and has a blocking portion 58 that is formed integrally at the open end of the trench 54. Thereby, a void for passing a gas (gas flow path 59) that is sealed by the conduit insulating film 55 is formed inside the trench 54. The gas flow path 59 is a long and narrow flow path that is demarcated by the conduit insulating film 55, a peripheral surface of which is constituted of an insulating material. In this preferred embodiment, the conduit insulating film 55 is formed of a silicon oxide film, and the gas flow path 59 is demarcated by a silicon oxide film.

The conduit insulating film 55 may be an insulating film that is formed independently only on the inner surface of the trench 54. However, as shown in FIG. 6, it may be a film that is formed in a state that a second insulating film 60 which covers the first principal surface 33 of the second semiconductor substrate 24 partially enters into the trench 54.

In the pressure sensor 16, a gas flows into the second cavity 47 from the outer end portion 53 of the gas conduit 29 via the gas flow path 59. The gas that has flowed into the second cavity 47 passes through the through holes 49, 50 and flows into the space 46, thereby acting on the membrane 38. The membrane 38 vibrates and undergoes deformation by a pressure resulting from the gas. At this time, a change in resistance of the piezoresistances R1 to R4 that occurs due to a physical distortion of the membrane 38 is detected and taken out as an electrical signal corresponding to a magnitude of the pressure of the gas.

With reference to FIG. 4 and FIG. 8, a description will be given of a structure of the acceleration sensor 17. The acceleration sensor 17 is formed in the second sensor region 37. The acceleration sensor 17 is formed by processing for partially removing the first semiconductor substrate 23 of the substrate stacked structure 30. The acceleration sensor 17 is covered and sealed by the second semiconductor substrate 24.

The acceleration sensor 17 includes an X axis sensor 61 and a Y axis sensor 62. The X axis sensor 61 detects an acceleration in the first direction X that acts on the sensor structure body 6. The Y axis sensor 62 detects an acceleration in the second direction Y that acts on the sensor structure body 6. The X axis sensor 61 and the Y axis sensor 62 are adjacent to each other at an interval in the first direction X. The Y axis sensor 62 has substantially the same configuration as that obtained by turning the X axis sensor 61 by 90 degrees in a plan view. Hereinafter, a specific description will be given of an inner structure of the X axis sensor 61. A description of an inner structure of the Y axis sensor 62 will be omitted by giving the same reference signs as those of the X axis sensor 61 in FIG. 4.

The X axis sensor 61 is formed in a state of floating from a bottom surface of a third cavity 63 formed on the first principal surface 31 side of the first semiconductor substrate 23. The third cavity 63 can be formed by selectively etching the first semiconductor substrate 23. With reference to FIG. 4, the third cavity 63 is a portion that is surrounded by the first frame portion 41 constituted of a portion of the first semiconductor substrate 23 which is not etched. That is, two cavities of the third cavity 63 and the first cavity 40 surrounded by the first frame portion 41 are disposed in the first semiconductor substrate 23 so as to be aligned in the first direction X.

The X axis sensor 61 includes a comb-like fixed electrode 64 and a comb-like movable electrode 65 in combination with the fixed electrode 64, each of which is constituted of a part of the first semiconductor substrate 23. The fixed electrode 64 is supported by the first frame portion 41 via a first connection portion 66. The movable electrode 65 is supported by the first frame portion 41 in the first direction X via a freely expandable elastic structure (second connection portion 67). When the X axis sensor 61 receives an acceleration, the second connection portion 67 that is connected to the movable electrode 65 undergoes contraction and expansion. A movement distance of the second connection portion 67 at this time is detected as a change in electrostatic capacitance between the fixed electrode 64 and the movable electrode 65 and taken out as an electrical signal that corresponds to the acceleration.

A first separation structure 68 for the fixed electrode 64 and a second separation structure 69 for the movable electrode 65 are formed at the first frame portion 41.

The first separation structure 68 is a part of the first semiconductor substrate 23 that is surrounded by a first separation coupling portion 70. The first separation coupling portion 70 has an end portion that extends from the first principal surface 31 of the first semiconductor substrate 23 up to the third cavity 63 and is exposed inside the third cavity 63. The first separation coupling portion 70 is constituted of an insulating film. In this preferred embodiment, the first separation coupling portion 70 is constituted of a silicon oxide film. The first separation coupling portion 70 electrically separates the first separation structure 68 from other portions of the first semiconductor substrate 23. A first contact portion 71 for the fixed electrode 64 is formed on the first separation structure 68. The first contact portion 71 is electrically connected to the fixed electrode 64 via the first separation structure 68 and a wiring that is not shown.

The second separation structure 69 is a part of the first semiconductor substrate 23 that is surrounded by a second separation coupling portion 72. The second separation coupling portion 72 has an end portion that extends from the first principal surface 31 of the first semiconductor substrate 23 up to the third cavity 63 and is exposed inside the third cavity 63. The second separation coupling portion 72 is constituted of an insulating film. In this preferred embodiment, the second separation coupling portion 72 is constituted of a silicon oxide film. The second separation coupling portion 72 electrically separates the second separation structure 69 from other portions of the first semiconductor substrate 23. A second contact portion 73 for the movable electrode 65 is formed on the second separation structure 69. The second contact portion 73 is electrically connected to the movable electrode 65 via the second separation structure 69 and a wiring that is not shown.

Wirings (first to fourth wirings 74A to 74D) extend from the first contact portion 71 and the second contact portion 73 and are electrically connected to the electrode pads 21. The electrode pads 21 may include, for example, a first pad 75A, a second pad 75B, a third pad 75C, a fourth pad 75D and a fifth pad 75E, all of which are for the acceleration sensor 17. The first pad 75A and the second pad 75B are pads for the X axis sensor 61, and the third pad 75C and the fourth pad 75D are pads for the Y axis sensor 62. The fifth pad 75E is a substrate terminal that is connected to the first semiconductor substrate 23 via a fifth wiring 74E.

[Method for Forming Exposed Structure of Gas Conduit 29 According to First Preferred Embodiment]

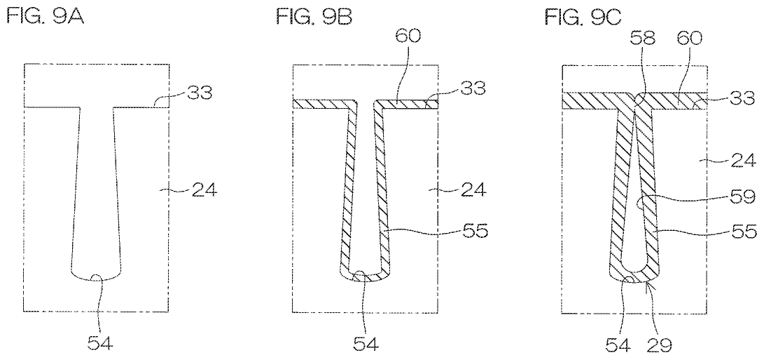

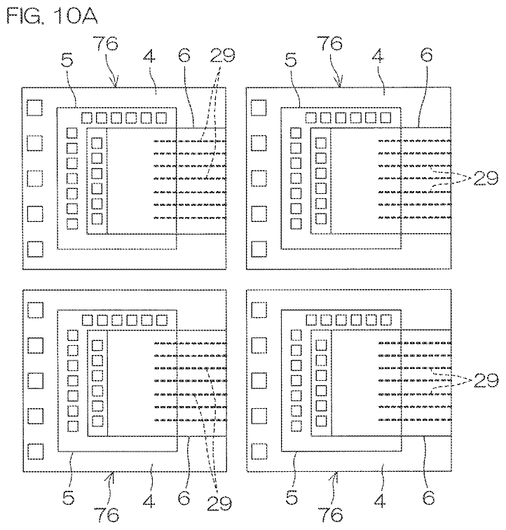

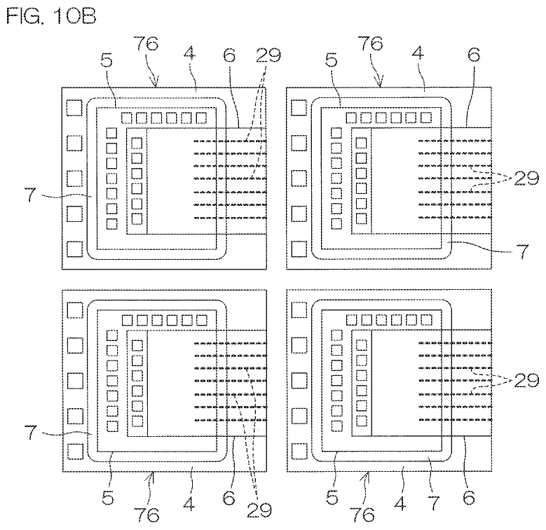

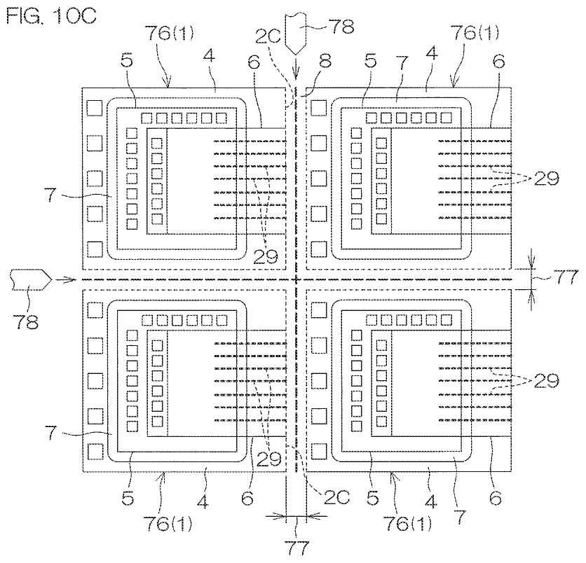

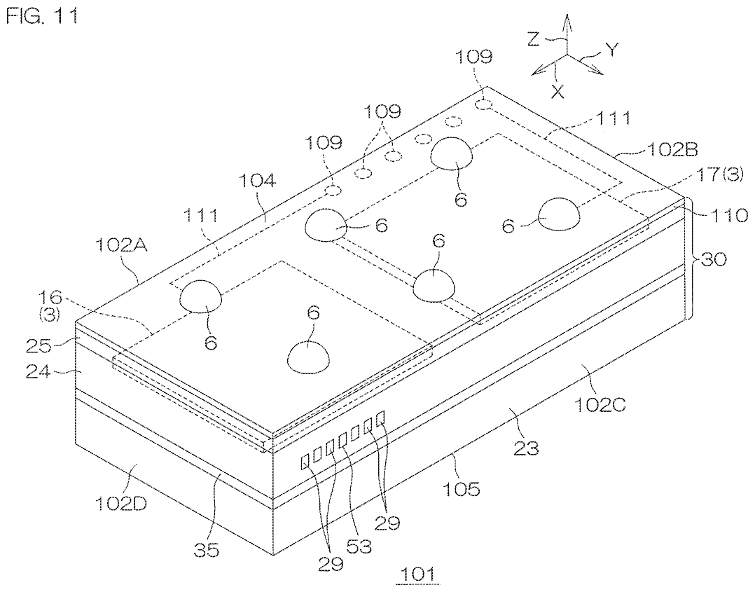

FIG. 9A to FIG. 9C are each a diagram which shows a step related to formation of the gas conduit 29 shown in FIG. 6. FIG. 10A to FIG. 10C are each a diagram which shows a step related to singulation of the plurality of semiconductor devices 1.

As described previously, the semiconductor device 1 has a structure in which the gas conduit 29 is formed of the conduit insulating film 55 and the conduit insulating film 55 is exposed from the sealing resin 8. A method for forming the exposed structure of the gas conduit 29 will be described with reference to FIG. 9A to FIG. 9C and FIG. 10A to FIG. 10C.

With reference to FIG. 9A, in order that the gas conduit 29 is formed, the trench 54 is first formed in the second semiconductor substrate 24. The trench 54 may be formed, for example, by an anisotropic deep RIE (reactive ion etching). Next, with reference to FIG. 9B and FIG. 9C, the second semiconductor substrate 24 in which the trench 54 has been formed is subjected to a thermal oxidation process, and the inner surface of the trench 54 is exposed to an oxygen atmosphere. Thereby, the conduit insulating film 55 is formed on the inner surface of the trench 54. In the thermal oxidation process, the insulating film grows in a space portion of the trench 54 from the inner surface of the trench 54 as shown in FIG. 9B, continuing until an interior of the trench 54 is sealed by the insulating film at the open end of the trench 54 as shown in FIG. 9C. The conduit insulating film 55 is thereby formed in the trench 54, and the gas flow path 59 is also formed inside the conduit insulating film 55. It is noted that the conduit insulating film 55 may be formed by, for example, a CVC (chemical vapor deposition) method, etc.

In order that the gas conduit 29 is exposed from the sealing resin 8, for example, many sensor structure bodies 6 are formed on a semiconductor wafer (not shown) that forms the substrate stacked structure 30 and, thereafter, the semiconductor wafer is subjected to dicing. Thereby, a semi-finished chip 76 (element chip) of the semiconductor device 1 excluding the sealing resin 8 is singulated and manufactured. Thereafter, the semi-finished chip 76 is transferred to a resin molding step. In the resin molding step, as shown in FIG. 10A, the plurality of semi-finished chips 76 are set in order on a substrate (not shown).

Next, with reference to FIG. 10B, the sensor structure body 6 and the circuit substrate 5 of the semi-finished chip 76, are covered by a liquid-type curing sealing material 7. The liquid-type curing sealing material 7 can be formed, for example, by a dispensing method for ejecting a liquid sealing material to each of the semi-finished chips 76, a printing/sealing method for transferring a printing sheet on which a sealing material has been printed in advance, etc.

Next, with reference to FIG. 10C, the plurality of semi-finished chips 76 are collectively sealed by the sealing resin 8. The plurality of semi-finished chips 76 can be sealed by known sealing technologies, for example, a transfer method, a compression method, etc. Thereafter, a dicing blade 78 is scanned along a dicing line 77 set between the semi-finished chips 76 adjacent to each other, by which the sealing resin 8 is cut and each of the semiconductor devices 1 is singulated. The dicing blade 78 is scanned so as to cross the plurality of gas conduits 29 that extend parallel to each other, by which the gas conduit 29 is exposed on the third end surface 2C of the sealing resin 8 after being cut.

As described so far, in the semiconductor device 1 according to this preferred embodiment, since the pressure sensor 16 and the acceleration sensor 17 are covered by the common sealing resin 8, it is possible to detect both a pressure around the semiconductor device 1 and an acceleration acting on the semiconductor device 1 by one chip.

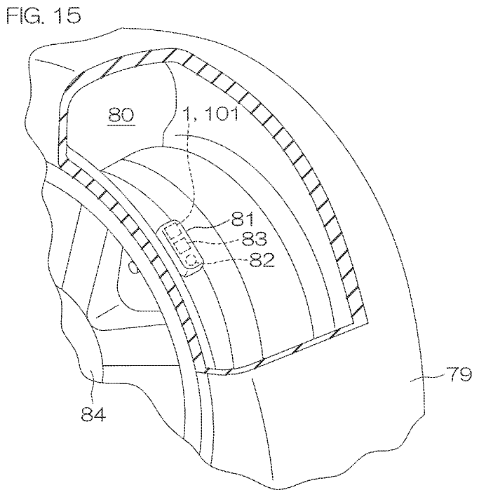

Further, a protective structure of the membrane 38 of the pressure sensor 16 is not made of a case, for example, a glass cover, etc., but formed of the sealing resin 8. Thereby, it is possible to suppress breakage of the semiconductor device 1 resulting from vibration, shock, etc., and to improve the degree of freedom on where the semiconductor device 1 is disposed and how it is handled. For example, where the semiconductor device 1 is used as a tire pressure sensor shown in FIG. 15, an inner space 80 of a tire 79 is a harsh environment exposed to vibration and high temperatures. However, the semiconductor device 1 is a sensor that is covered by the sealing resin 8 and excellent in durability and, therefore, can be used safely and reliably even in such a harsh environment.

Further, since the gas conduit 29 that lies across the inside and the outside of the sealing resin 8 is used as a port for introducing a gas into the pressure sensor 16, it is possible to prevent foreign matter, dust, etc., contained in the gas from entering a mechanical structure (for example, inside the second cavity 47 or the space 46) of the pressure sensor 16. As a result, it is possible to improve the detection accuracy of the pressure sensor 16.

[Entire Configuration of Semiconductor Device 101 According to Second Preferred Embodiment]

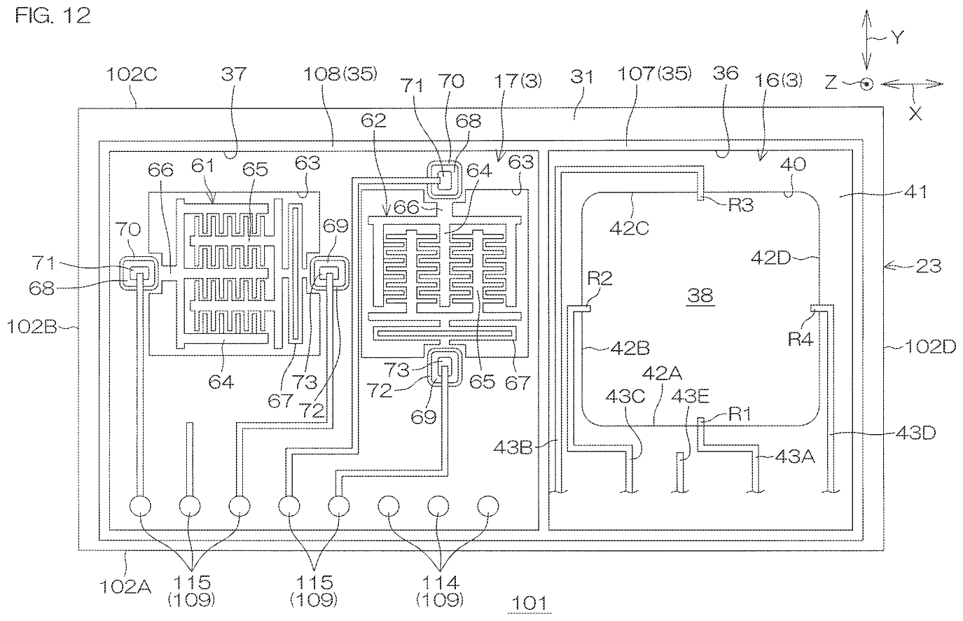

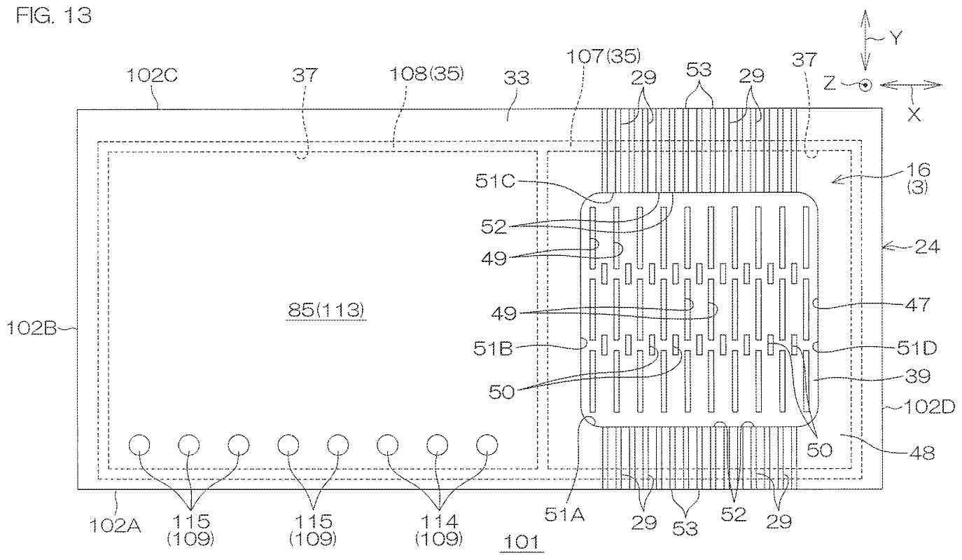

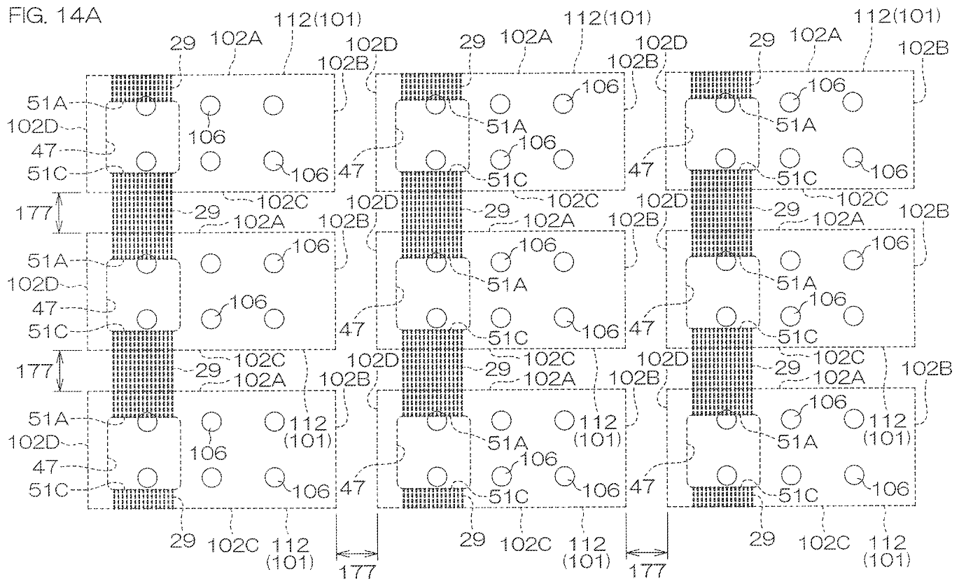

FIG. 11 is a schematic perspective view of a semiconductor device 101 according to the second preferred embodiment of the present disclosure. FIG. 12 is a schematic plan view that shows a sensor structure 3 of a first semiconductor substrate 23 shown in FIG. 11. FIG. 13 is a schematic plan view that shows a sensor structure 3 of a second semiconductor substrate 24 shown in FIG. 11. Hereinafter, a structure corresponding to the structure described in the semiconductor device 1 according to the first preferred embodiment will be given the same reference sign, with a description thereof omitted.

The semiconductor device 101 is a semiconductor device to which a WL-CSP (wafer level chip size package) is applied as a package mode. The semiconductor device 101 is formed, for example, as a chip in a rectangular parallelepiped shape. The semiconductor device 101 is the WL-CSP and, therefore, may be referred to as a semiconductor chip or a semiconductor die.

As with the first preferred embodiment, three directions that are orthogonal to each other are defined as a first direction X, a second direction Y, and a third direction Z. The third direction Z may be a thickness direction of the semiconductor device 101. The first direction X and the second direction Y may be respectively a direction along a first end surface 102A and a third end surface 102C of the semiconductor device 101 as well as a direction along a second end surface 102B and a fourth end surface 102D thereof. The first end surface 102A and the third end surface 102C are surfaces that are parallel to each other. The second end surface 102B and the fourth end surface 102D are surfaces that are orthogonal to the first end surface 102A and the third end surface 102C and also parallel to each other.

The semiconductor device 101 has a first principal surface 104 that is surrounded by the first to fourth end surfaces 102A to 2D and a second principal surface 105 on a side opposite to the first principal surface 104. The first principal surface 104 of the semiconductor device 101 may be a mounting surface that is bonded to a mounting substrate. The first to fourth end surfaces 102A to 2D of the semiconductor device 101 may be respectively referred to as first to fourth outer end surfaces 102A to 2D.

A plurality of external terminals 106 are provided on the first principal surface 104 of the semiconductor device 101. Each external terminal 106 is formed in a spherical shape or a semi-spherical shape, for example, by using a metal material such as soldering, etc. The plurality of external terminals 106 are arrayed on the first principal surface 104 regularly (for example, in a matrix form). Although FIG. 11 shows six external terminals 106, less than six or more than six external terminals 106 may be provided. The semiconductor device 101 is flip-chip bonded to the mounting substrate by bonding the plurality of external terminals 106 to an island (not shown) of the mounting substrate.

In the semiconductor device 101, an outer shape of the semiconductor device 101 is formed by a substrate stacked structure 30. A pair of principal surfaces that face the substrate stacked structure 30 in the third direction Z make up the first principal surface 104 and the second principal surface 105. The sensor structure 3 is formed inside a space between the first principal surface 104 and the second principal surface 105 of the semiconductor device 101. Further, a plurality of gas conduits 29 for introducing a gas into a pressure sensor 16 of the sensor structure 3 are opened on the first end surface 102A and the third end surface 102C of the semiconductor device 101 (only the third end surface 102C side is shown in FIG. 11).

The semiconductor device 101 is provided with a first semiconductor substrate 23, a second semiconductor substrate 24, and a lid substrate 25. The second semiconductor substrate 24 is stacked on the first semiconductor substrate 23, and the lid substrate 25 is stacked on the second semiconductor substrate 24. By appearance, the semiconductor device 101 has a substrate stacked structure 30 made up of the first semiconductor substrate 23, the second semiconductor substrate 24 stacked on the first semiconductor substrate 23 and the lid substrate 25 stacked on the second semiconductor substrate 24. An end surface of the substrate stacked structure 30 is exposed over the entire circumferential direction of the first to fourth end surfaces 102A to 102D of the semiconductor device 101. The first to fourth end surfaces 102A to 102D of the semiconductor device 101 may be defined as first to fourth end surfaces 102A to 102D of each of the first semiconductor substrate 23, the second semiconductor substrate 24 and the lid substrate 25.

In the semiconductor device 101, a bonding portion 35 seals a plurality of sensor regions 36, 37 from the outside and, therefore, may be referred to as an outer seal ring. Of the bonding portion 35, for example, a portion of a quadrilateral annular shape that demarcates the first sensor region 36 may be referred to as a first seal ring 107, and a portion of a quadrilateral annular shape that demarcates the second sensor region 37 may be referred to as a second seal ring 108.

A plurality of through electrodes 109 are formed in the second sensor region 37. With reference to FIG. 11 to FIG. 13, the plurality of through electrodes 109 penetrate through the second semiconductor substrate 24. The plurality of through electrodes 109 also penetrate through the lid substrate 25 and are electrically connected to the plurality of external terminals 106 on the lid substrate 25. For example, a front surface insulating film 110 is formed on the first principal surface 104 of the lid substrate 25. Each of the through electrodes 109 may be electrically connected to the external terminal 106 via a front surface wiring 111 that is led out from each of the through electrodes 109 onto the front surface insulating film 110. In FIG. 11, for clarification, only some of the front surface wirings 111 are shown, with the remaining front surface wirings 111 omitted.

The plurality of through electrodes 109 electrically connect the plurality of external terminals 106 with both of the pressure sensor 16 and an acceleration sensor 17. The plurality of through electrodes 109 may include a first through electrode 114 for the pressure sensor 16 and a second through electrode 115 for the acceleration sensor 17. In this preferred embodiment, the first through electrode 114 and the second through electrode 115 are not formed in the first sensor region 36 but they are selectively formed in the second sensor region 37. The first through electrode 114 and the second through electrode 115 are concentrated in the second sensor region 37, which contributes to an improved detection accuracy of a gas pressure by the pressure sensor 16. For example, many gas conduits 29 are formed in the first sensor region 36. The first through electrode 114 and the second through electrode 115 are concentrated in the second sensor region 37, thereby securing a large space for the gas conduits 29 in the first sensor region 36. Accordingly, the number of the gas conduits 29 can be increased to efficiently introduce a gas into the pressure sensor 16.

With reference to FIG. 12, wirings (first to fourth wirings 43A to 43D) extending respectively from piezoresistances R1 to R4 are each connected to the plurality of through electrodes 109 (first through electrodes 114). In FIG. 12, due to a limited space of the diagram, a mode of connecting the first to fourth wirings 43A to 43D with the plurality of through electrodes 109 (first through electrodes 114) is not shown. A fifth wiring 43E is a wiring for connecting a substrate that is connected to the first semiconductor substrate 23, and is connected to the through electrode 109 (first through electrode 114).

With reference to FIG. 13, the gas conduit 29 extends from a second cavity 47 up to the end surfaces 102A to 102D of the semiconductor device 1 (second semiconductor substrate 24). In this preferred embodiment, of four side surfaces 51A to 51D of the second cavity 47, the plurality of gas conduits 29 extend in a mutually reverse direction from the first side surface 51A and the third side surface 51C parallel to the first end surface 102A and the third end surface 102C of the semiconductor device 1. The plurality of gas conduits 29 pass through the second frame portion 48 and extend up to the first end surface 102A and the third end surface 102C of the semiconductor device 1. The second side surface 51B as a remaining side surface of the second cavity 47 may be parallel to the second end surface 102B of the semiconductor device 1, and the fourth side surface 51D may be parallel to the fourth end surface 102D of the semiconductor device 1.

With reference to FIG. 13, the gas conduit 29 includes an inner end portion 52 on the second cavity 47 side and an outer end portion 53 on the first end surface 102A side and the third end surface 102C side of the semiconductor device 1. The outer end portion 53 of the gas conduit 29 is opened on the first end surface 102A and on the third end surface 102C of the semiconductor device 1 (refer to FIG. 11).

In the gas conduit 29, a trench 54 is formed by selectively digging down a part of a linear region of the second frame portion 48 from the first side surface 51A and the third side surface 51C of the second cavity 47 up to the first end surface 102A and the third end surface 102C of the semiconductor device 101. A conduit insulating film 55 extends from the inner end portion 52 of the trench 54 on the second cavity 47 side to the outer end portion 53 of the trench 54 on the first end surface 102A side and the third end surface 102C side of the second semiconductor substrate 24 along a length direction of the trench 54.

In the semiconductor device 101, first to fourth wirings 74A to 74D that extend from a first contact portion 71 and a second contact portion 73 (refer to FIG. 8) are each connected to the plurality of through electrodes 109 (second through electrode 115). A fifth wiring 74E is a wiring for connecting a substrate that is connected to the first semiconductor substrate 23 and is connected to the through electrode 109 (second through electrode 115).

With reference to FIG. 13, the semiconductor device 1 is further provided with a control circuit 113 in the substrate stacked structure 30. In this preferred embodiment, the second sensor region 37 of the second semiconductor substrate 24 may be a circuit region 85 in which the control circuit 113 is formed. A charge amplifier for amplifying an electrical signal output from the pressure sensor 16 and the acceleration sensor 17, a filter circuit (low-pass filter: LPF, etc.) for taking out a specific frequency component of the electrical signal, a logic circuit for performing a logical calculation of the electrical signal after filtering, etc., are formed inside the circuit region 85. These circuits are constituted of CMOS devices, for example.

[Method for Forming Exposed Structure of Gas Conduit 29 According to Second Preferred Embodiment]

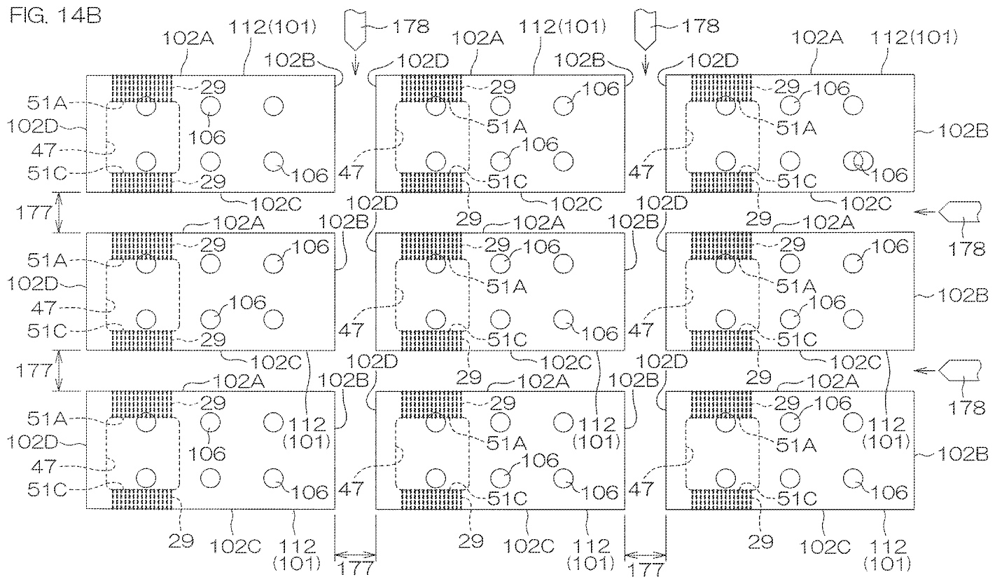

FIG. 14A is a diagram that shows a step related to singulation of the plurality of semiconductor devices 101. FIG. 14B is a diagram that shows a step subsequent to that of FIG. 14A.

In the step of forming the gas conduit 29 of the semiconductor device 101, the trench 54 and the conduit insulating film 55 are formed in accordance with the aforementioned steps of FIG. 7A to FIG. 7C. The gas conduit 29 having the gas flow path 59 inside the conduit insulating film 55 is, thereby, formed.

In order that the gas conduit 29 is exposed from the semiconductor device 101, with reference to FIG. 14A, many semiconductor devices 101 are formed, for example, in an element region 112 set in a semiconductor wafer (not shown) that forms the substrate stacked structure 30. The element region 112 is demarcated, for example, by a lattice-shaped dicing line 177. The dicing line 177 is formed by the substrate stacked structure 30.

In FIG. 14A, the gas conduit 29 crosses the dicing line 177 and lies across the plurality of semiconductor devices 101. More specifically, the first side surface 51A of the second cavity 47 of a certain semiconductor device 101 is communicatively connected to the third side surface 51C of the second cavity 47 of the semiconductor device 101 that is adjacent to the above-described semiconductor device 101 by the gas conduit 29 that crosses the dicing line 177. That is, the gas conduit 29 inside the above-described semiconductor device 101 is integrally connected with the gas conduit 29 inside the adjacent semiconductor device 101.

Next, with reference to FIG. 14B, a dicing blade 178 is scanned along the dicing line 177, thereby singulating each of the semiconductor devices 101. The dicing blade 178 is scanned so as to cross the gas conduit 29 inside the dicing line 177, by which the gas conduit 29 is exposed on the first end surface 102A and the third end surface 102C of each of the semiconductor devices 101 after being cut.

As described so far, in the semiconductor device 101 according to this preferred embodiment, the pressure sensor 16 and the acceleration sensor 17 are mounted on the common WL-CSP type semiconductor device 101. It is, thus, possible to detect a pressure around the semiconductor device 101 and an acceleration acting on the semiconductor device 101 by one chip.

Further, a protective structure of the membrane 38 of the pressure sensor 16 is not made of a case, for example, a glass cover, etc., but formed of the substrate stacked structure 30. It is, thereby, possible to suppress breakage of the semiconductor device 101 resulting from vibration, shock, etc., and to improve the degree of freedom on where the semiconductor device 101 is disposed and how it is handled. Where the semiconductor device 101 is used, for example, as a tire pressure sensor as shown in FIG. 15, an inner space 80 of a tire 79 is a harsh environment that is exposed to vibration and high temperatures. However, since the semiconductor device 101 is a sensor that is constituted of the substrate stacked structure 30 and excellent in durability, it can be used safely and reliably even in such a harsh environment.

Further, since the gas conduit 29 that lies across the inside and the outside of the semiconductor device 101 is used as a port for introducing a gas into the pressure sensor 16, it is possible to prevent foreign matter, dust, etc., contained in the gas from entering a mechanical structure (for example, inside the second cavity 47 or the space 46) of the pressure sensor 16. As a result, it is possible to improve the detection accuracy of the pressure sensor 16.

[Uses of Semiconductor Device 1, 101]

FIG. 15 is a diagram that shows an installation state of the semiconductor device 1, 101 when used as a tire pressure sensor. In FIG. 15, the tire 79 of an automobile is partially removed to show an interior of the tire 79.

The aforementioned semiconductor device 1, 101 can be used for various applications that need detection of a gas pressure and an acceleration and can be used, for example, as a tire pressure sensor for an automobile. Since the semiconductor device 1, 101 is in particular provided with the pressure sensor 16, it can be assembled into a direct-type air pressure detection system that directly detects a pressure of an inner space 80 (space between the tire 79 and a wheel 84) of the tire 79.

The semiconductor device 1, 101 may be assembled into a sensor module 81 that includes an electric battery 82, a transmitter 83, etc. As shown in FIG. 15, the sensor module 81 may be attached on a front surface of the wheel 84 that is the inner space 80 of the tire 79. The sensor module 81 directly measures an air pressure of the tire 79 by the pressure sensor 16 of the semiconductor device 1 and sends information thereof from the transmitter 83 to a receiver (not shown) on a vehicle body side by wireless communication, by which a driver can be notified of an abnormality. Further, the sensor module 81 also has the built-in acceleration sensor 17 in addition to the pressure sensor 16. Therefore, where there is found a considerable change in acceleration resulting from vibration or shock that is received by the tire 79 during running, for example, due to a decrease in air pressure, it is possible to detect the change and notify of the decrease in air pressure to the driver.

Although a description has been so far given of the preferred embodiments of the present disclosure, the present disclosure can be also executed by other embodiments.

For example, the transmitter 83 shown in FIG. 15 may be built in the semiconductor device 1. In this case, the transmitter 83 may be formed, for example, in a preliminary sensor region 85 (region on the acceleration sensor 17) of the second semiconductor substrate 24 in the second sensor region 37 shown in FIG. 5 and FIG. 13. It is, thereby, possible to save a space for the transmitter 83 of the sensor module 81 and to downsize the sensor module 81. The semiconductor device 1 or the sensor module 81 may also have a built-in temperature sensor for detecting a temperature inside the tire.

Further, a structure of the pressure sensor 16 and that of the acceleration sensor 17 are not restricted to that shown in FIG. 4 to FIG. 8 and in FIG. 11 to FIG. 13 but can be changed whenever necessary. There may be adopted, for example, a structure of a bourdon tube-type pressure sensor, that of a piezoresistance-type acceleration sensor and that of a heat detecting-type acceleration sensor.

The preferred embodiments of the present disclosure so far described are examples in every respect and should not be understood in a limited manner and are intended to include changes in every respect.

The following features can be extracted from descriptions of the present specification and the drawings.

### Appendix 1-1

A semiconductor device (1) including

a sensor structure body (6) that has a hollow space (47) inside,

a gas conduit (29) that extends from an end surface (27C) of the sensor structure body (6) toward the hollow space (47) to introduce a gas into the hollow space (47) from outside the sensor structure body (6),

a pressure sensor (16) that is formed inside the sensor structure body (6) and has a membrane (38) which is able to vibrate by actions of a pressure of the gas introduced into the hollow space (47) via the gas conduit (29),

an acceleration sensor (17) that is formed inside the sensor structure body (6) to detect an acceleration which has acted on the sensor structure body (6), and

a sealing resin (8) that covers the sensor structure body (6), in which

the gas conduit (29) includes an inner end portion (52) on the hollow space (47) side and an outer end portion (53) on the end surface (27C) side of the sensor structure body (6), and

the outer end portion (53) of the gas conduit (29) is opened on an end surface (2C) of the sealing resin (8).

### Appendix 1-2

The semiconductor device (1) according to Appendix 1-1 in which the end surface (27C) of the sensor structure body (6) and the outer end portion (53) of the gas conduit (29) are flush with the end surface (2C) of the sealing resin (8).

### Appendix 1-3

The semiconductor device (1) according to Appendix 1-2 in which an outline (28) of the end surface (27C) of the sensor structure body (6) is exposed to the end surface (2C) of the sealing resin (8) over an entire circumference thereof, and

the end surface (27C) of the sensor structure body (6) is surrounded by the end surface (2C) of the sealing resin (8).

### Appendix 1-4

The semiconductor device (1) according to any one of Appendix 1-1 to Appendix 1-3 in which

the sensor structure body (6) includes semiconductor substrates (23, 24),

the gas conduit (29) includes a trench (54) that connects the hollow space (47) and an end surface (27C) of the semiconductor substrates (23, 24) in the semiconductor substrate (23, 24) and also includes a conduit insulating film (55) that is formed on an inner surface of the trench (54), and

the conduit insulating film (55) is formed in a tubular shape that extends from an inner end portion (52) on the hollow space (47) side of the trench (54) up to an outer end portion (53) of the trench (54) on the end surface (27C) side of the semiconductor substrates (23, 24) along a length direction of the trench (54) and is blocked at an upper end of the trench (54) in a depth direction of the trench (54).

### Appendix 1-5

The semiconductor device (1) according to Appendix 1-4 in which

the semiconductor substrates (23, 24) include a silicon substrate, and

the conduit insulating film (55) includes a silicon oxide film.

### Appendix 1-6

The semiconductor device (1) according to Appendix 1-4 or Appendix 1-5 in which

the semiconductor substrates (23, 24) have a stacked structure (30) of a first semiconductor substrate (23) and a second semiconductor substrate (24) stacked on the first semiconductor substrate (23),

the membrane (38) is formed on the first semiconductor substrate (23),

the second semiconductor substrate (24) includes a protective layer (39) that forms a bottom portion of the hollow space (47) and also covers the membrane (38), and

through holes (49, 50) that allow a gas introduced into the hollow space (47) via the gas conduit (29) to circulate to the membrane (38) are formed in the protective layer (39).

### Appendix 1-7

The semiconductor device (1) according to Appendix 1-6 in which

a plurality of the through holes (49, 50) are regularly arrayed in the protective layer (39).

### Appendix 1-8

The semiconductor device (1) according to Appendix 1-7 in which

the plurality of through holes (49, 50) include a plurality of through slits.

### Appendix 1-9

The semiconductor device (1) according to any one of Appendix 1-1 to Appendix 1-8 including a liquid-type curing sealing material (7) that is interposed between the sensor structure body (6) and the sealing resin (8) to cover the sensor structure body (6).

### Appendix 1-10

The semiconductor device (1) according to Appendix 1-9 in which

the sensor structure body (6) includes a first covered portion (18) that is covered by the liquid-type curing sealing material (7) and a second covered portion (19) that protrudes from the first covered portion (18) and is also directly covered by the sealing resin (8) but not in contact with the liquid-type curing sealing material (7), and

the gas conduit (29) extends from the first covered portion (18) up to the end surface (2C) of the sealing resin (8) via the second covered portion (19).

### Appendix 1-11

The semiconductor device (1) according to Appendix 1-9 or Appendix 1-10 in which

the liquid-type curing sealing material (7) includes a silicone resin.

### Appendix 1-12

The semiconductor device (1) according to any one of Appendix 1-1 to Appendix 1-11 in which

the acceleration sensor (17) includes an electrostatic capacitance type acceleration sensor (17) that includes a fixed electrode (64) and a movable electrode (65) which faces the fixed electrode (64).

### Appendix 1-13

The semiconductor device (1) according to any one of Appendix 1-1 to Appendix 1-12 further including a circuit substrate (5) that includes a control circuit electrically connected to the pressure sensor (16) and the acceleration sensor (17), in which

the sensor structure body (6) is stacked on an upper surface (13) of the circuit substrate (5).

### Appendix 1-14

The semiconductor device (1) according to Appendix 1-13 further including a supporting substrate (4) for supporting the circuit substrate (5) and the sensor structure body (6), in which

the sealing resin (8) covers the circuit substrate (5) and the sensor structure body (6) on an upper surface region of the supporting substrate (4).

### Appendix 1-15

The semiconductor device (1) according to any one of Appendix 1-1 to Appendix 1-14 which is used as a tire pressure sensor for detecting information on an inner pressure of a tire.

### Appendix 1-16

A sensor module (81) for detecting information on an inner pressure of a tire,

the sensor module (81) including the semiconductor device (1) according to any one of Appendix 1-1 to Appendix 1-14 and

a transmitter (83) that sends the information on the inner pressure of the tire detected by the semiconductor device (1) to a receiver.

### Appendix 2-1

A semiconductor device (101) that is a WL-CSP (wafer level chip size package) type,

the semiconductor device (101) including
semiconductor substrates (23, 24, 25) that have a hollow space (47) inside to form an outer shape of the semiconductor device (101),

a gas conduit (29) that extends from end surfaces (102A, 102C) of the semiconductor substrates (23, 24, 25) toward the hollow space (47) to introduce a gas into the hollow space (47) from outside the semiconductor substrates (23, 24, 25),

a pressure sensor (16) that is formed inside the semiconductor substrates (23, 24, 25) and has a membrane (38) which is able to vibrate by actions of a pressure of the gas introduced into the hollow space (47) via the gas conduit (29), and

an acceleration sensor (17) that is formed inside the semiconductor substrates (23, 24, 25) to detect an acceleration that has acted on the semiconductor substrates (23, 24, 25), in which

the gas conduit (29) includes an inner end portion (52) on the hollow space (47) side and an outer end portion (53) on the end surfaces (102A, 102C) sides of the semiconductor substrates (23, 24, 25), and

the outer end portion (53) of the gas conduit (29) is opened on the end surfaces (102A, 102C) of the semiconductor substrates (23, 24, 25).

According to this configuration, it is possible to provide the semiconductor device (101) in which the pressure sensor (16) and the acceleration sensor (17) are packaged in the WL-CSP type. Since the pressure sensor (16) and the acceleration sensor (17) are packaged in the WL-CSP type, it is possible to detect both a pressure around the semiconductor device (101) and an acceleration acting on the semiconductor device (101) by one chip.

### Appendix 2-2

The semiconductor device (101) according to Appendix 2-1 in which

the end surfaces (102A, 102C) of the semiconductor substrates (23, 24, 25) and the outer end portion (53) of the gas conduit (29) are formed so as to be flush with each other.

### Appendix 2-3

The semiconductor device (101) according to Appendix 2-1 or Appendix 2-2 in which

the gas conduit (29) includes a trench (54) that is formed in the semiconductor substrates (23, 24, 25) and connects the hollow space (47) with end surfaces (102A, 102C) of the semiconductor substrates (23, 24, 25) and a conduit insulating film (55) that is formed on an inner surface of the trench (54), and

the conduit insulating film (55) is formed in a tubular shape that extends from an inner end portion (52) of the trench (54) on the hollow space (47) side up to the outer end portion (53) of the trench (54) on the end surfaces (102A, 102C) sides of the semiconductor substrates (23, 24, 25) along a length direction of the trench (54) and is blocked at an upper end of the trench (54) in a depth direction.

### Appendix 2-4

The semiconductor device (101) according to Appendix 2-3 in which

the semiconductor substrates (23, 24, 25) include a silicon substrate, and

the conduit insulating film (55) includes a silicon oxide film.

### Appendix 2-5

The semiconductor device (101) according to Appendix 2-3 or Appendix 2-4 in which

the semiconductor substrates (23, 24, 25) have a stacked structure (30) of a first semiconductor substrate (23) and a second semiconductor substrate (24) that is stacked on the first semiconductor substrate (23),

the membrane (38) is formed on the first semiconductor substrate (23),

the second semiconductor substrate (24) includes a protective layer (39) that forms a bottom portion of the hollow space (47) and also covers the membrane (38), and

through holes (49, 50) that allow a gas introduced into the hollow space (47) via the gas conduit (29) to circulate to the membrane (38) are formed in the protective layer (39).

### Appendix 2-6

The semiconductor device (101) according to Appendix 2-5 in which

the plurality of through holes (49, 50) that are regularly arrayed are formed in the protective layer (39).

### Appendix 2-7

The semiconductor device (101) according to Appendix 2-6 in which

the plurality of through holes (49, 50) include a plurality of through slits.

### Appendix 2-8

The semiconductor device (101) according to any one of Appendix 2-5 to Appendix 2-7 in which

the stacked structure (30) further includes a third semiconductor substrate (25) that is stacked on the second semiconductor substrate (24),

the semiconductor device (101) including

a through electrode (109) that is electrically connected to the pressure sensor (16) and the acceleration sensor (17) to penetrate through the second semiconductor substrate (24) and the third semiconductor substrate (25), and

an external terminal (106) that is formed on the third semiconductor substrate (25) and electrically connected to the through electrode (109).

### Appendix 2-9

The semiconductor device (101) according to Appendix 2-8 including

a bonding portion (35) that bonds a space between the first semiconductor substrate (23) and the second semiconductor substrate (24) to demarcate a first sensor region (36) for the pressure sensor (16) and a second sensor region (37) for the acceleration sensor (17) on the first semiconductor substrate (23), in which

the through electrode (109) includes a first through electrode (114) that is electrically connected to the pressure sensor (16) and a second through electrode (115) that is electrically connected to the acceleration sensor (17), and

the first through electrode (114) and the second through electrode (115) are formed so as to concentrate in the second sensor region (37).

### Appendix 2-10

The semiconductor device (101) according to Appendix 2-8 or Appendix 2-9 in which

the external terminal (106) includes a terminal for mounting the semiconductor device (101) by flip-chip bonding.

### Appendix 2-11

The semiconductor device (101) according to any one of Appendix 2-1 to Appendix 2-10 in which

the acceleration sensor (17) includes an electrostatic capacitance type acceleration sensor (17) that includes a fixed electrode (64) and a movable electrode (65) which faces the fixed electrode (64).

### Appendix 2-12

The semiconductor device (101) according to any one of Appendix 2-1 to Appendix 2-11 in which

the semiconductor substrates (23, 24, 25) further include a control circuit (113) that is electrically connected to the pressure sensor (16) and the acceleration sensor (17).

### Appendix 2-13

The semiconductor device (101) according to any one of Appendix 2-1 to Appendix 2-12 that is formed in a quadrilateral shape having a first end surface (102A), a second end surface (102B), a third end surface (102C) and a fourth end surface (102D) in a plan view, in which

the outer end portion (53) of the gas conduit (29) is opened at least on two end surfaces (102A, 102C) of the first end surface (102A), the second end surface (102B), the third end surface (102C), and the fourth end surface (102D).

### Appendix 2-14

The semiconductor device (101) according to any one of Appendix 2-1 to Appendix 2-13 that is used as a tire pressure sensor for detecting information on an inner pressure of a tire.

### Appendix 2-15

A sensor module (81) for detecting information on an inner pressure of a tire,

the sensor module (81) including the semiconductor device (101) according to any one of Appendix 2-1 to Appendix 2-13 and

a transmitter (83) that sends to a receiver the information on the inner pressure of the tire detected by the semiconductor device (101).

What is claimed is:

1. A semiconductor device comprising:
a sensor structure body that has a hollow space inside;
a gas conduit that extends from an end surface of the sensor structure body to the hollow space to introduce a gas into the hollow space from outside the sensor structure body;
a pressure sensor that is formed inside the sensor structure body and has a membrane which is able to vibrate by actions of a pressure of the gas introduced into the hollow space via the gas conduit;
an acceleration sensor that is formed inside the sensor structure body to detect an acceleration which has acted on the sensor structure body; and
a sealing resin that covers the sensor structure body; wherein
the gas conduit includes an inner end portion on the hollow space side and an outer end portion on the end surface side of the sensor structure body, and
the outer end portion of the gas conduit is opened on an end surface of the sealing resin.

2. The semiconductor device according to claim 1, wherein
the end surface of the sensor structure body and the outer end portion of the gas conduit are flush with the end surface of the sealing resin.

3. The semiconductor device according to claim 2, wherein
an outline of the end surface of the sensor structure body is exposed on the end surface of the sealing resin over an entire circumference thereof, and
the end surface of the sensor structure body is surrounded by the end surface of the sealing resin.

4. The semiconductor device according to claim 1, wherein
the sensor structure body includes a semiconductor substrate,
the gas conduit includes a trench that connects the hollow space with an end surface of the semiconductor substrate in the semiconductor substrate, and a conduit insulating film conduit that is formed on an inner surface of the trench, and
the conduit insulating film is formed in a tubular shape that extends from an inner end portion of the trench on the hollow space side to an outer end portion of the trench on the end surface side of the semiconductor substrate along a length direction of the trench and is blocked at an upper end of the trench in a depth direction of the trench.

5. The semiconductor device according to claim 4, wherein
the semiconductor substrate includes a silicon substrate, and
the conduit insulating film includes a silicon oxide film.

6. The semiconductor device according to claim 4, wherein
the semiconductor substrate has a stacked structure of a first semiconductor substrate and a second semiconductor substrate that is stacked on the first semiconductor substrate,
the membrane is formed on the first semiconductor substrate,
the second semiconductor substrate forms a bottom portion of the hollow space and also includes a protective layer that covers the membrane, and
a through hole that allows a gas introduced into the hollow space via the gas conduit to circulate to the membrane is formed in the protective layer.

7. The semiconductor device according to claim 6, wherein
a plurality of the through holes are regularly arrayed in the protective layer.

8. The semiconductor device according to claim 7, wherein
the plurality of through holes include a plurality of through slits.

9. The semiconductor device according to claim 1 including a liquid-type curing sealing material that is interposed between the sensor structure body and the sealing resin to cover the sensor structure body.

10. The semiconductor device according to claim 9, wherein
the sensor structure body includes a first covered portion that is covered by the liquid-type curing sealing material and a second covered portion that protrudes from the first covered portion and is also directly covered by the sealing resin but not in contact with the liquid-type curing sealing material, and
the gas conduit extends from the first covered portion to the end surface of the sealing resin via the second covered portion.

11. The semiconductor device according to claim 9, wherein
the liquid-type curing sealing material includes a silicone resin.

12. The semiconductor device according to claim 1, wherein
the acceleration sensor includes an electrostatic capacitance-type acceleration sensor that has a fixed electrode and a movable electrode which faces the fixed electrode.

13. The semiconductor device according to claim 1 further including a circuit substrate that includes a control circuit electrically connected to the pressure sensor and the acceleration sensor, wherein
the sensor structure body is stacked on an upper surface of the circuit substrate.

14. The semiconductor device according to claim 13 further including a supporting substrate that supports the circuit substrate and the sensor structure body, wherein
the sealing resin covers the circuit substrate and the sensor structure body on an upper surface region of the supporting substrate.

15. The semiconductor device according to claim 1 that is used as a tire pressure sensor for detecting information on an inner pressure of a tire.

16. A sensor module for detecting information on an inner pressure of a tire, wherein
the sensor module includes
the semiconductor device according to claim 1, and
a transmitter that sends the information on the inner pressure of the tire detected by the semiconductor device to a receiver.
